(19) United States
(12) Patent Application Publication
(10) Pub. No.: US 2002/0021137 A1
(43) Pub. Date: Feb. 21, 2002

(54) Method for calibrating a semiconductor testing device, a semiconductor testing apparatus, and a method for testing a semiconductor device

(75) Inventor: Nobuaki Takeuchi, Tokyo (JP)

Correspondence Address: DARBY & DARBY P.C., 805 Third Avenue, New York, NY, 10022, US

(73) Assignee: Ando Electric Co., Ltd.

(21) Appl. No.: 09/888,614

(22) Filed: Jun. 25, 2001

(30) Foreign Application Priority Data
Jun. 29, 2000 (JP) P2000-197040

(51) Int. Cl. G01R 31/308

(52) U.S. Cl. 324/753

(57) ABSTRACT

The method for calibrating a semiconductor testing device, comprises the steps of: changing a beam emitted from a light source into a linear beam; sending the linear beam through an electro optic element provided above a target device onto a measuring line on the target device; detecting a variation in polarization of the beam reflected from the measuring line; calculating an electric field distribution or a voltage distribution on the measuring line of the target device based on the variation in polarization; and moving a calibrating device, which produces an electric field from a predetermined point, to specify a measurable point or range.

### BACKGROUND OF THE INVENTION

1. Field of the Invention

The present invention relates to an apparatus for testing a semiconductor device using an EOS (Electro-Optic Sampling) process for measuring a voltage or an electric field based on an electro-optic effect.

2. Description of the Related Art

A conventional apparatus for testing a semiconductor device is disclosed in “Handy High Impedance Probe Using EOS”, Fifteenth Light Wave Sensing Technique Research Society, 1995, pp. 123-129), by Shinagawa et al.

FIG. 12 shows an improved conventional apparatus for testing a semiconductor device. A light source 101, driven by a light source driving circuit 117, emits laser light. The laser light emitted from the light source 101 is condensed by a condensing lens 102, and is sent to a curved surface mirror 103. The laser light reflected by the curved surface mirror 103 illuminates an electro-optic element 104. The laser light is reflected by a reflecting mirror 105 provided below the electro-optic element 104, passes through a wavelength plate 107, and is divided into two beams by a polarization beam splitter 108. The beams are condensed by micro-lens arrays 109-1 and 109-2, and are received by ling sensors 110-1 and 110-2. The light path 18 schematically indicates the laser light path.

The light source 101, the condensing lens 102, and the curved surface mirror 103 are arranged so that the laser light straightly reaches the boundary between the electro-optic element 104 and the reflecting plate 105. That is, the cross-sectional shape of the laser beam at the boundary between the electro-optic element4 and the reflecting plate 5 is approximately straight.

The micro lens arrays 109-1 and 109-2 are composite lens in which a plurality of lenses are straightly aligned. The straight or elliptic laser beam passes through the lenses.

In the DUT 106 which is the test target device, the voltage varies depending on the input to the DUT 106 or the output from the DUT 106. The variations in the voltage change the electric field in the electro-optic element 104 neighboring the DUT 106. The laser beam passing through the electro-optic element 104 is polarized by the variations in the electric field. The polarization varies depending on the linear or elliptic cross-sectional shape of the laser beam.

The line sensors 110 output signals, and the output signals are amplified by amplifying circuits 111-1 and 111-2, and the difference between the signals is obtained by a differential circuit 126. The difference signal is sampled and held by a sample-hold circuit 112. The output from the sample-hold circuit 112 is sent through a selecting circuit 113 to an A/D converting circuit 114, is converted into a digital signal by the A/D converting circuit 114, and is input to a processing/display circuit 115. The selecting circuit 113 can select one of a plurality of signals. A plurality of amplifying circuits amplify the outputs from the line sensors in a parallel manner. That is, the amplifying circuit 111-1 amplifies the output signal from the line sensor 110-1 while the amplifying circuit 111-2 amplifies the output signal from the line sensor 110-2.

To produce light pulses from the light source 101, the measuring signals obtained from the measuring points of the DUT 106, which are the output signals from the line sensors 1 10-1 and 110-2, must be repetitive signals synchronized with a trigger signal St. A timing producing circuit 16 produces a pulsed light emission timing signal Sp so that the phase is delayed by δt whenever the trigger signal St is input. Thus, the light source 101 produces the pulsed light.

The pulsed light is emitted through the condensing lens 102, the curved surface mirror 103, and the electro-optic element 104 onto the reflecting plate 5 which is placed on the DUT 106. The measuring signals at the measuring points of the DUT 106 are sampled and held by the sample-hold circuit 112 synchronously with a sample-hold timing signal Ssh at the same time.

A number N of signals output from the sample-hold circuit 112 is selected one at a time by the selecting circuit 113 according to a selection timing signal Ssel. The A/D converting circuit 114 A/D-converts the signal selected by the selecting circuit 113 one at a time synchronously with an A/D conversion timing signal Sad. That is, the N number of signals obtained by a single sample-hold step are A/D converted one at a time. The above operation is repeated, and all the voltages and electric fields of the DUT 106 can be measured.

The processing/display device 115 multiplies the digital data obtained by the A/D converting circuit 114 by the sensitivity of the measurement system, converts the digital data into the voltages and electric fields at the measuring points of the DUT 106, and displays the obtained voltages and electric fields.

However, the conventional technique has the following problems. First, the measurable points of the line sensors are not specified. It is therefore difficult to specify the point of the electro-optic element which is to make contact with the DUT.

The expanse of the linear laser beam (the longitudinal length of the line) is unclear. It is therefore difficult to specify which point of the DUT is being measured. Thus, the measuring range is unclear, the display of the measurement results is not reliable.

The length of the path from the light source to the electro-optic element is not regular, and the measuring time varies depending on the measuring points of the electro-optic element.

The intensity distribution, the loss over the light path, and the sensitivity vary depending on the positions of the electro-optic element and the line sensor. Thus, the measuring sensitivity varies depending on the measuring points.

Further, there is no device for directly detecting the dielectric constant distribution.

Further, there is no device for directly detecting the direction of the electric field.

### BRIEF SUMMARY OF THE INVENTION

It is therefore an object of the present invention to provide a method for calibrating a semiconductor device, an apparatus for testing a semiconductor device, and a method for testing a semiconductor device, which are easy to operate and which achieve a high accuracy.

In the first aspect of the present invention, the method for calibrating a semiconductor testing device comprises the steps of: changing a beam emitted from a light source into a linear beam; sending the linear beam through an electro optic element provided above a target device onto a measuring line on the target device; detecting a variation in polarization of the beam reflected from the measuring line; calculating an electric field distribution or a voltage distribution on the measuring line of the target device based on the variation in polarization; and moving a calibrating device, which produces an electric field from a predetermined point, to specify a measurable point or range.

In the second aspect of the present invention, the method according to the first aspect further comprises the step of displaying the measurable point or range.

In the third aspect of the present invention, the method according to the first aspect of the present invention further comprises the step of calculating a relative delay time distribution of the beam on the measuring line of the target device.

In the fourth aspect of the present invention, the apparatus for testing a semiconductor device comprises: a beam changer for changing a beam emitted from a light source into a linear beam, and sending the linear beam through an electro optic element provided above a target device onto a measuring line on the target device; a detector for detecting a variation in polarization of the beam reflected from the measuring line; a calculator for calculating an electric field distribution or a voltage distribution on the measuring line of the target device based on the variation in polarization; and a mark indicating a measurable point or range.

In the fifth aspect of the present invention, the apparatus for testing a semiconductor device comprises: a beam changer for changing a beam emitted from a light source into a linear beam, and sending the linear beam through an electro optic element provided above a target device onto a measuring line on the target device; a detector for detecting a variation in polarization of the beam reflected from the measuring line; a calculator for calculating an electric field distribution or a voltage distribution on the measuring line of the target device based on the variation in polarization; and a recorder for recording a measurable point or range.

In the sixth aspect of the present invention, the method of the present invention for calibrating a semiconductor device, comprises the steps of: changing a beam emitted from a light source into a linear beam; sending the linear beam through an electro optic element provided above a target device onto a measuring line on the target device; detecting a variation in polarization of the beam reflected from the measuring line; calculating an electric field distribution or a voltage distribution on the measuring line of the target device based on the variation in polarization; correcting the electric field distribution or the voltage distribution based on a relative delay time distribution of the beam on the measuring line of the target device; and displaying variations in the corrected electric field distribution or the voltage distribution.

In the seventh aspect of the present invention, the method according to the sixth aspect further comprises the step of recording values obtained by multiplying the relative delay time distribution of the beam on the measuring line by −1.

In the eighth aspect of the present invention, the method of the present invention for calibrating a semiconductor device comprises the steps of: changing a beam emitted from a light source into a linear beam; sending the linear beam through an electro optic element provided above a target device onto a measuring line on the target device; detecting a variation in polarization of the beam reflected from the measuring line; calculating an electric field distribution or a voltage distribution on the measuring line of the target device based on the variation in polarization; calculating a dielectric constant obtained by dividing a travel time of a pulse between two predetermined points on the measuring line by a distance between the points, and multiplying the divided value by the speed of light; and displaying the dielectric constant.

In the ninth aspect of the present invention, the method according to the eighth aspect further comprises the steps of calculating and displaying a dielectric constant distribution on the measuring line.

In the tenth aspect of the present invention, the method for calibrating a semiconductor device, comprises the steps of: changing a beam emitted from a light source into a linear beam; sending the linear beam through an electro optic element provided above a target device onto a measuring line on the target device; detecting a variation in polarization of the beam reflected from the measuring line; calculating an electric field distribution or a voltage distribution on the measuring line of the target device based on the variation in polarization; detecting variations in the electric field distribution or the voltage distribution when a pulse travels on the measuring line; and specifying a traveling direction of the pulse.

In the eleventh aspect of the present invention, the method according to the tenth aspect further comprises the steps of: converting the detecting the variations in the electric field distribution or the voltage distribution into a frequency; adapting a real part of the first term of the frequency to a cosine function; and specifying the traveling direction of the pulse from an angle of the cosine functions for a plurality of points on the measuring line.

In the twelfth aspect of the present invention, the method according to the eleventh aspect further comprises the step of displaying the traveling direction of the pulse with the voltage distribution or the electric field distribution.

In the thirteenth aspect of the present invention, the apparatus for testing a semiconductor device, comprises: a beam changer for changing a beam emitted from a light source into a linear beam, and sending the linear beam through an electro optic element provided above a target device onto a measuring line on the target device; a detector for detecting a variation in polarization of the beam reflected from the measuring line; a calculator for calculating an electric field distribution or a voltage distribution on the measuring line of the target device based on the variation in polarization; and an electrode provided in the measurable range.

In the fourteenth aspect of the present invention, the method for testing a semiconductor device, comprises the steps of: changing a beam emitted from a light source into a linear beam; sending the linear beam through an electro optic element provided above a target device onto a measuring line on the target device; detecting a variation in polarization of the beam reflected from the measuring line; calculating an electric field distribution or a voltage distribution on the measuring line of the target device based on the variation in polarization; calculating a reciprocal number of a light intensity at a point on the measuring line; and multiplying a voltage or an electric field at the point on the measuring line by the reciprocal number to correct the voltage or the electric field.

In the fifteenth aspect of the present invention, the method according to the fourteenth aspect further comprises the step of: recording the reciprocal number of light intensity at the point on the measuring line.

In the sixteenth aspect of the present invention, the method according to the fourteenth aspect further comprises the steps of: detecting the variation in polarization of the reflected beam with different al light receiving sections; and calculating the light intensity based on the sum of outputs from the differential light receiving sections.

In the seventeenth aspect of the present invention, the method further comprises the steps of: detecting the variation in polarization of the reflected beam with a single light receiving section; and calculating the light intensity based on an output from the single light receiving section indicating the absence of the voltage or the electric field in the target device.

According to the present invention, when measuring the voltage or the electric field of the target device, the measurable range, or the measurable points can be determined.

The present invention specifies and displays the measuring points. Therefore, when bringing the electro-optic element, or a holder for holding the electro-optic element close to the target device, the positional relationship between the measuring points of the target device and the electro-optic element can be easily adjusted.

The display indicates the measurable points, or the measurable range so that the points at which the voltages or the electric fields are measured correspond to the measured data units in one-to-one correspondence.

The present invention calibrates the delay times of the signal at the measuring points, thereby eliminating errors due to the delay times from the measured data.

The present invention can directly measure the dielectric constant and the dielectric constant distribution, which could not be measured by the conventional technique. Further, the present invention can directly measure the traveling direction of the pulse at a specific voltage or in a specific electric field.

The present invention corrects the light intensities, thereby eliminating errors due to the sensitivities varying depending on the positions in the measuring range.

### BRIEF DESCRIPTION OF THE DRAWINGS

FIG. 1 is a block diagram showing the semiconductor testing device of the present invention.

FIG. 2 is a diagram showing the details of the light receiving section for receiving a laser beam in the present invention.

FIG. 3 is a timing chart for explaining the operation of the present invention.

FIG. 4 is a diagram for explaining the operation for detecting the measurable points in the semiconductor testing apparatus of the present invention.

FIG. 5 is an example of the measurement result displayed in a processing/display device of the present invention.

FIG. 6 is a diagram showing an indication of the measurable range in the present invention.

FIG. 7 is a diagram showing an example of the relative delay time distribution in the present invention.

FIG. 8 is a diagram showing the details of the correction of the delay times in the present invention.

FIG. 9 is a diagram showing an example of the dielectric constant distribution in the present invention.

FIG. 10 is a diagram showing an example of the indication of the traveling direction of the pulse at the specific voltage or in the specific electric field in the present invention.

FIG. 11 is a diagram showing an example of the sensitivity distribution depending on the positions in the present invention.

FIG. 12 is a diagram showing the conventional semiconductor testing apparatus.

### DETAILED DESCRIPTION OF THE INVENTION

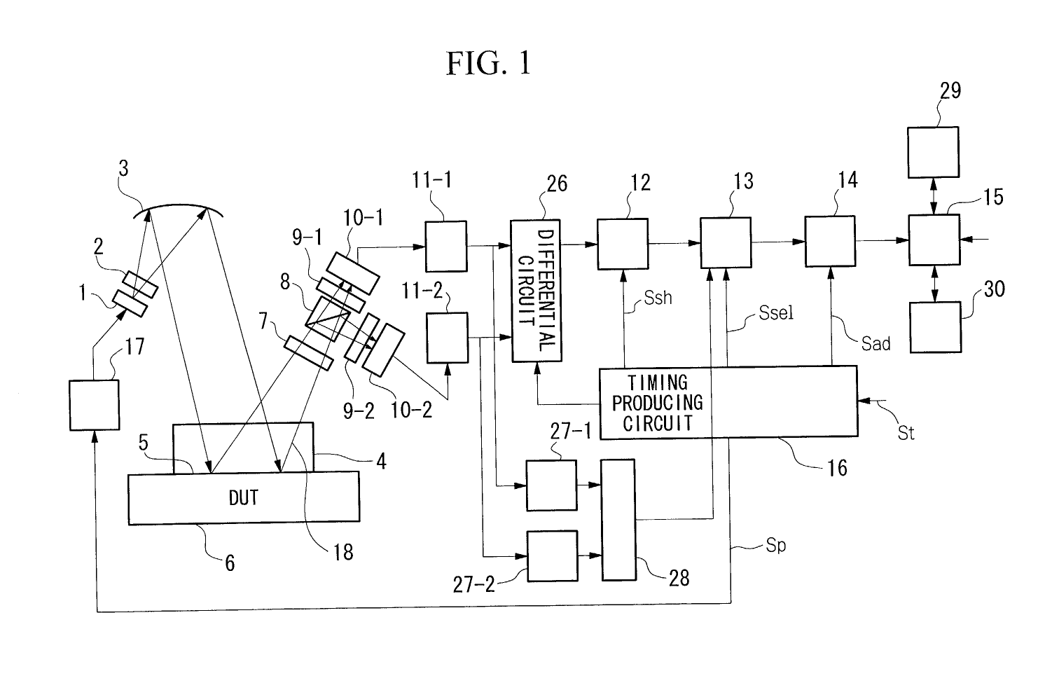

FIG. 1 is a block diagram showing an embodiment of the apparatus for testing a semiconductor device according to the present invention. A light source 1, driven by a light source driving circuit 17, emits laser light. The laser light emitted from the light source 1 is condensed by a condensing lens 2, and is sent to a curved surface mirror 3. The laser light reflected by the curved surface mirror 3 illuminates an electro-optic element 4. The laser light is reflected by a reflecting mirror 5 provided below the electro-optic element 4, passes through a wavelength plate 7, and is divided into two beams by a polarization beam splitter.8. The beams are condensed by micro-lens arrays 9-1 and 9-2, and are received by line sensors 10-1 and 10-2. A light path 18 schematically indicates the laser light path.

The light source 1, the condensing lens 2, and the curved surface mirror 3 are arranged so that the laser light straightly reaches the boundary between the electro-optic element 4 and the reflecting plate 5. That is, the cross-sectional shape of the laser beam at the boundary between the electro-optic element 4 and the reflecting plate 5 is approximately straight.

The micro lens arrays 9-1 and 9-2 are composite lenses in which a plurality of lenses are straightly aligned. The straight or elliptic laser beam passes through the lenses.

In a DUT 6 which is the test target device, the voltage varies depending on the input to the DUT 6 or the output from the DUT 6. The variations in the voltage change the electric field in the electro-optic element 4 neighboring the DUT 6. The laser beam passing through the electro-optic element 4 is polarized by the variations in the electric field. The polarization varies depending on the linear or elliptic cross-sectional shape of the laser beam.

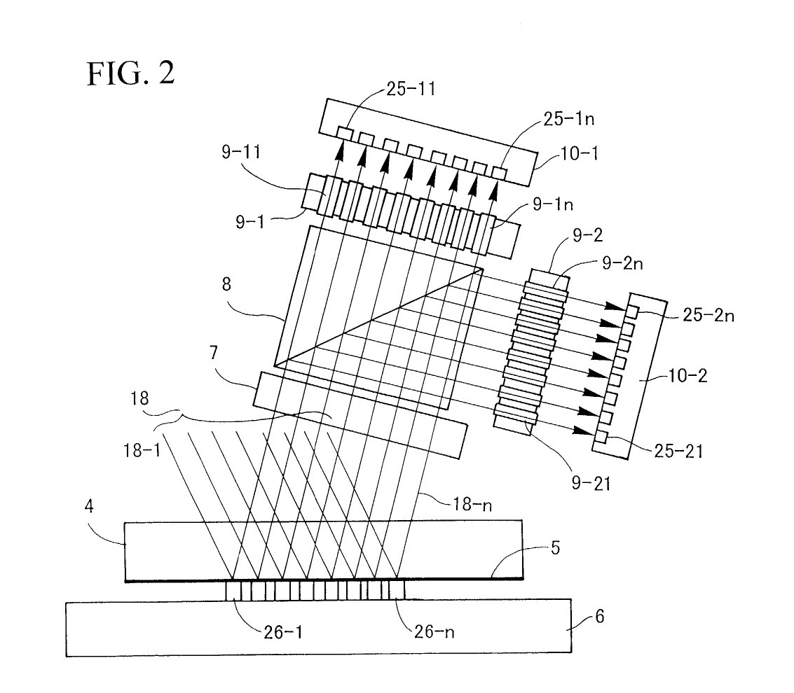

FIG. 2 shows the details of a light receiving section for receiving the laser beam. The light path 18 schematically indicates the path of the laser beam. The cross-sectional shape of the light path 18 is one-dimensional, that is, linear. Therefore, it is assumed that the light path 18 comprises beams 18-1 to 18-n. The beams 18-1 to 18-n which enter the electro-optic element 4 pass through different points in the electro-optic element 4.

The electric field produced by the DUT 6 is radiated through pins 26-1 to 26-n to the electro-optic element 4. The electric field varies the polarization of the laser beams which are the beams 18-1 to 18-n.

The wavelength plate 7 is adjusted to have a polarization angle to divide the laser beam equally by the polarization beam splitter 8. The polarization beam splitter 8 varies the separation ratio depending on the amount of polarization of the entering beam. The laser beam which has had its polarization changed by the electro-optic element 4 also has its amplitude changed by passes through the polarization beam splitter 8 so that the amplitude of the laser beam is changed.

By means of this, the variations in voltage which depend on the position on the DUT 6 become variations in amplitude which depend on the positions in the cross-section of the laser beam. The laser beam whose amplitude has changed is received through the micro lens arrays 9-1 and 9-2 by the line sensors 10-1 and 10-2. The line sensors 10-1 and 10-2 convert the variations in amplitude of the laser beam into variations in amplitude of electric signals. Thus, the line sensors 10-1 and 10-2 provide the electric signals in proportion to the electric fields or voltages at the positions in the DUT 6.

The separated outputs from the polarization beam splitter 8 are in inverse proportion to each other. That is, as one of the outputs is increased, the other is decreased. Therefore, the difference between the output electric signals from the line sensors 10-1 and 10-2 can reliably provides the signal component from the DUT 6.

As shown in FIG. 1, the output signals from the line sensors 10-1 and 10-2 are amplified by amplifying circuits 11-1 and 11-2, and a differential circuit 26 provides the difference between the signals. The difference signal is sampled and held by a sample-hold circuit 12. The output from the sample-hold circuit 12 is transferred through a selecting circuit, is converted into a digital signal by an A/D converting circuit 14, and is input to a processing display circuit 15. The selecting circuit 13 can select one of a plurality of signals. A plurality of amplifying circuits amplify the outputs from the line sensors in a parallel manner. That is, the amplifying circuit 11-1 amplifies the output signal from the line sensor 10-1 while the amplifying circuit 11-2 amplifies the output signal from the line sensor 10-2.

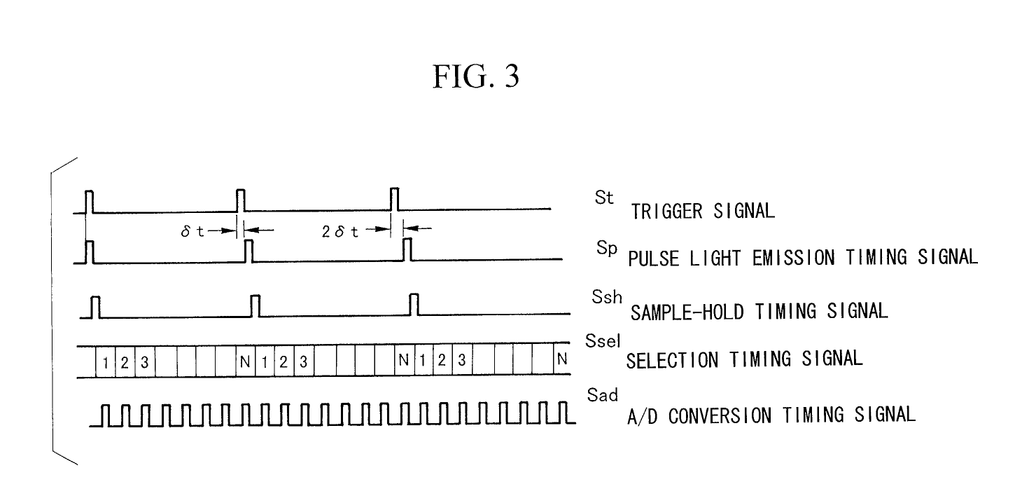

FIG. 3 is a timing chart for explaining the operation of the embodiment. In the following description, the operation in which the light source 1 emits pulsed light will be explained. To produce a pulsed light from the light source 1, the measuring signals obtained from the measuring points of the DUT6, which is the output signals from the line sensors 10-1 and 10-2, must be repetitive signals synchronized with a trigger signal St. A timing producing circuit 16 produces a pulsed light emission timing signal Sp so that the phase is delayed by 6t whenever the trigger signal St is input. Thus, the light source 1 produces the pulsed light.

The pulsed light is emitted through the condensing lens 2, the curved surface mirror 3, and the electro-optic element 4 onto the reflecting plate 5 which is placed on the DUT 6. The measuring signals at the measuring points of the DUT 6 are sampled and held by the sample-hold circuit 12 synchronously with a sample-hold timing signal Ssh at the same time.

The N signals output from the sample-hold circuit 12 are selected one at a time by the selecting circuit 13 according to a selection timing signal Ssel. The A/D converting circuit 14 A/D-converts the signals selected by the selecting circuit 13 one at a time synchronously with an A/D conversion timing signal Sad. That is, the N number of signals obtained by a single sample-hold step are A/D converted one at a time. The above operation is repeated, and all the voltages and electric fields of the DUT 6 can be measured.

The processing/display device 15 multiplies the digital data obtained by the A/D converting circuit 14 by the sensitivity of the measurement system, converts the digital data into the voltages and electric fields at the measuring points of the DUT 6, and displays the obtained voltages and electric fields. The display method may be a method including displaying the voltage distribution or the electric field distribution on the measuring line on the DUT 6, a method including selecting a plurality of points on the measuring line on the DUT 6 and displaying the voltage values or the electric field values at the selected points, or a method including displaying graphs indicating the variations in the voltage values or the electric field values at the selected points. Further, the display of the voltage distribution or the electric field distribution on the measuring line on the DUT 6 may vary over time. Further, in the method including selecting a plurality of points on the measuring line on the DUT 6 and displaying the voltage values or the electric field values at the selected points, the displayed values may vary over time.

The operation of the light receiving section will now be explained with reference to FIG. 2. The laser beam with the linear cross-sectional shape travels through the light path 18. It is assumed that the light path 18 comprises beams 18-1 to 18-n. The beams 18-1 to 18-n enter the electro-optic element 4, are reflected by the reflecting plate 5, pass through the electro-optic element 4, pass through the wavelength plate 7, and are separated into two beams by the polarization beam splitter.

One of the separated laser beam groups is condensed by the micro lens array 9-1, enters the line sensor 10-1, and is converted into electric signals by the line sensor 10-1. Specifically, the micro lens array 9-1 comprises n micro lenses 9-11 to 9-1n. The line sensor 10-1 has n light receiving faces 25-11 to 25-in. The beams 18-1, 18-2, . . . , 18-n are condensed by the micro lenses 9-11, 9-12, . . . , 9-1n, enter the light receiving faces 25-11, 25-12, . . . , and 25-1n, and are converted into the electric signals.

The other separated beams are condensed by the micro lens array 9-2, enter the line sensor 10-2, and are converted into electric signals. Specifically, the micro lens array 9-2 comprises n micro lenses 9-21 to 9-2n. The line sensor 10-2 has n light receiving faces 25-21 to 25-2n. The beams 18-1, 18-2, . . . , 18-n are condensed by the micro lenses 9-21, 9-22, . . . , 9-2n, enter the light receiving faces 25-21, 25-22, . . . , and 25-2n, and are converted into electric signals.

The electric field produced at the pin 26-1 which is one of the measuring points on the DUT 6 changes the polarization of the beam 18-1, and this beam 18-1 is received by the light receiving face 25-11 of the line sensor 10-1 and the light receiving face 25-21 of the line sensor 25-21. The line sensors 10-1 and 10-2 output the electric signals. The amplitudes of the electric signals vary depending on the electric field produced at the pin 26-1 which is one of the measuring points.

If the pins 26-1 to 26-n are eliminated, the operation of the present invention does not change as long as the DUT 6 is positioned close to the electro-optic element 4 because the electric field produced by the DUT 6 affects the electro-optic element 4.

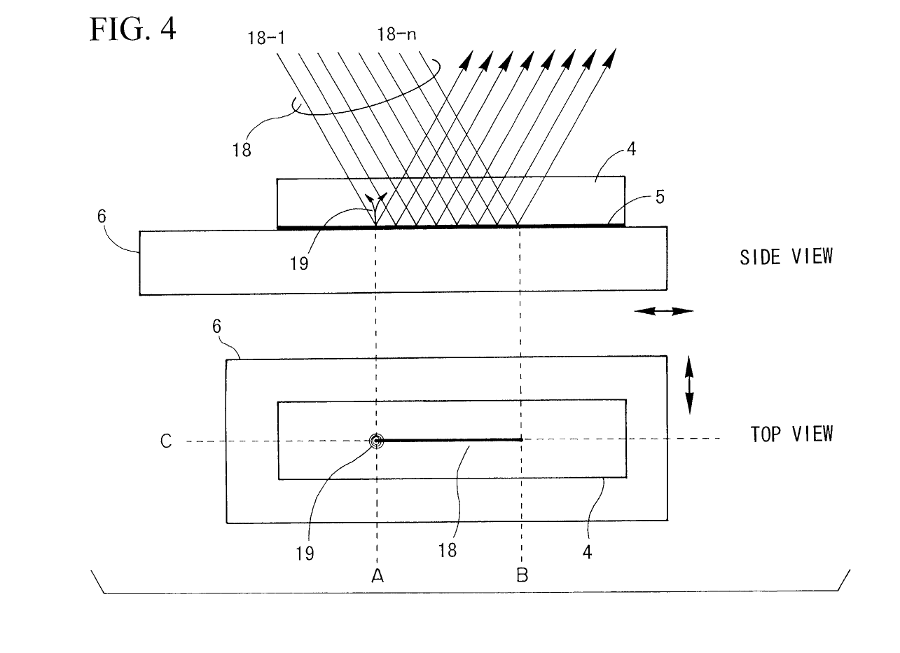

One feature of the present invention, that is, the method for calibrating the semiconductor testing apparatus, will now be explained. FIG. 4 is a diagram for explaining the operation for detecting the measurable points with the semiconductor testing apparatus of the embodiment. In the semiconductor testing apparatus, the electric field of the DUT 6 is measurable within the range indicated by the thick line which is on the straight line C and lies within the straight lines A and B. To detect the measurable points, a DUT 6 in which a single point produces an electric field 19 is prepared. The point which produces the electric field 19 must be known in advance. This DUT 6 is moved back and forth and from side to side in the semiconductor testing apparatus while the electric field is detected. Thus, the position at which the light path 18 is reflected by the reflecting plate 5 can be known. The measurable length can be calculated from the distance between the straight lines A and B.

When the laser beam is not visible, the light path cannot be visually checked. When the electro-optic element 4, the reflecting plate 5, and the other parts are held by holders, the holders may prevent the visual checking. According to the present invention, the position of the light path can be accurately specified.

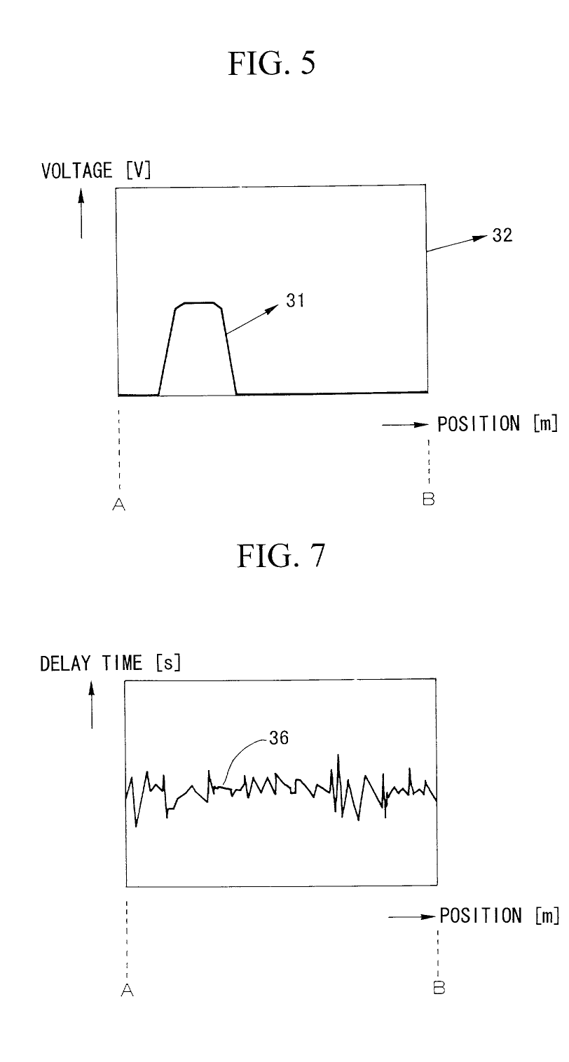

FIG. 5 shows an example of the measurement results indicated by the processing/display device 15. The example shows the voltage distribution on the measuring line on the DUT 6 as the measurement results. In the display area 32, the horizontal axis corresponds to the distance between the straight lines A and B (see FIG. 4), that is, the measuring section length, and the measured voltages are plotted on the vertical axis. Thus, the graph indicating the relationship between the position and the voltage, that is, the voltage distribution 31 can be displayed. This display clearly indicates the relationship between the measuring points and the measured values.

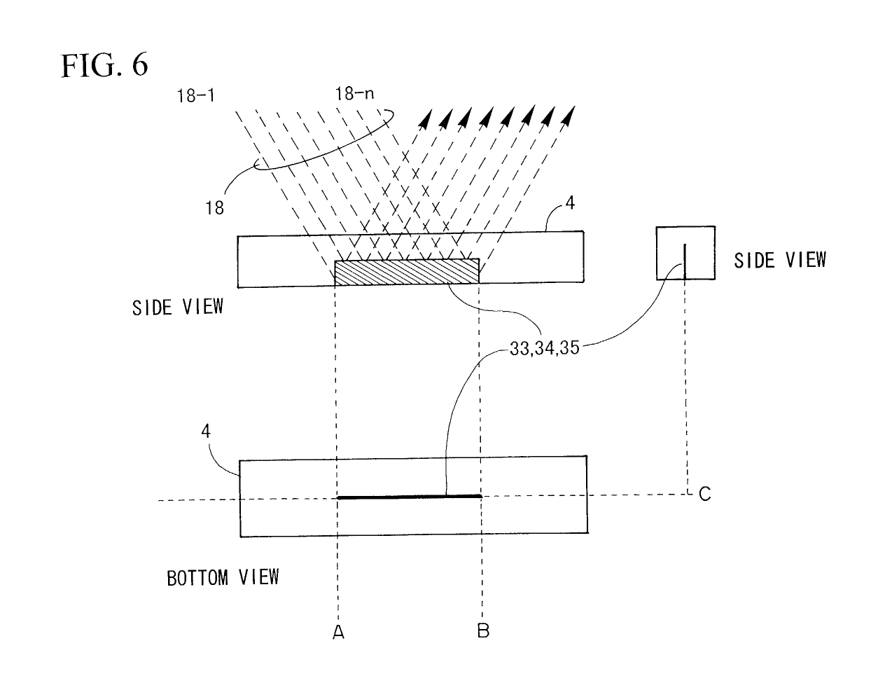

As shown in FIG. 6, the above-described measurable range is indicated on the electro-optic element 4, or the holder for holding the electro-optic element 4. The measurable range may be indicated on a protector for protecting the electro-optic element 4 or the holder. That is, the measurable range 33 which is on the straight line C and within the straight lines A and B is indicated on the bottom of the electro-optic element 4 or the holder. Similarly, the measurable ranges 34 and 35 are indicated on the sides. The single or multiple indications of the measurable range are used. The indications of the measurable range do not necessarily correspond to the range between the straight lines A and B, and may be within the range between the straight lines A and B.

The light path of the light pulse from the light source 1 to the electro-optic element 4 may slightly vary depending on the positions on the cross-section of the light path 8. In this case, the measuring times may differ between a point on the straight line A and a point on the straight line B, and the measurement may be inaccurate. To solve this problem, a relative delay time distribution depending on the measuring points is measured in advance. An example of the relative delay time distribution is shown in FIG. 7.

The relative delay time distribution can be obtained by observing the waveforms of the rising pulses measured in the DUT whose characteristics are known, and calculating the phase differences from the waveforms. The reciprocal numbers of the values in the relative delay time distribution in the measurable range are calculated by the processing/display device 15, and these numbers are recorded as the delay time correction values by a recorder 29. The values obtained by multiplying the relative delay times of the beam on the measuring line by −1 may be recorded.

When the characteristics of the DUT are not known, the variations of voltage obtained from the DUT over time are temporarily recorded by the recorder 29, and corrected based on the delay time correction values which have been recorded by the recorder 29.

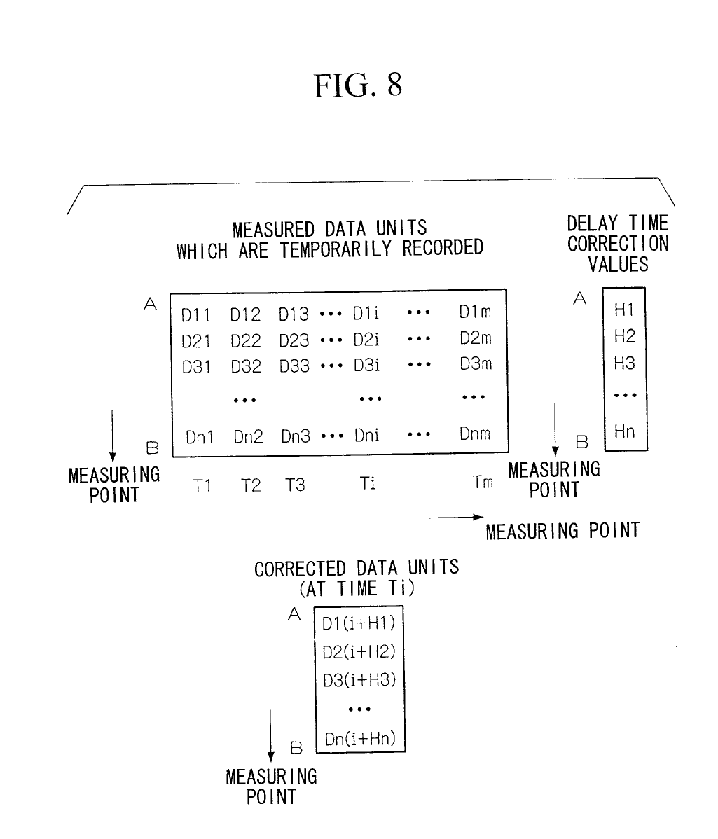

The details of the correction are shown in FIG. 8. The measured data D1i, D2i, . . . , Dni which are temporarily recorded by the recorder 29 are added to the delay correction values H1, H2, . . . , Hn, and are changed to D1(i+H1), D2(i+H2), . . . , Dn(i+Hn). That is, the reading points in the table which contains a plurality of measured data units at the different measuring points and at the different measuring times are changed based on the delay time correction values H1, H2, . . . , Hn.

Once the delay time correction values are recorded in the recorder 29, the values can be read from the recorder 29 for the next measurement, and therefore, the delay time correction values need not be calculated.

The method for obtaining the dielectric constant (dielectric constant) of the DUT 6 will now be explained. First, the travel time of the pulse signal from the straight line A to the straight line B through the DUT 6 is measured. Then, the travel time is divided by the distance between the straight line A and the straight line B, to obtain the travel speed of the pulse signal. The travel speed of the electric signal is inversely proportional to the dielectric constant. Therefore, the speed of light in a vacuum is divided by the measured travel speed of the pulse signal, to obtain the dielectric constant between the straight lines A and B. If the travel speed of the electric signal does not depend only on the dielectric constant, and if a coefficient depending on the structure of the DUT is needed, the value may be multiplied.

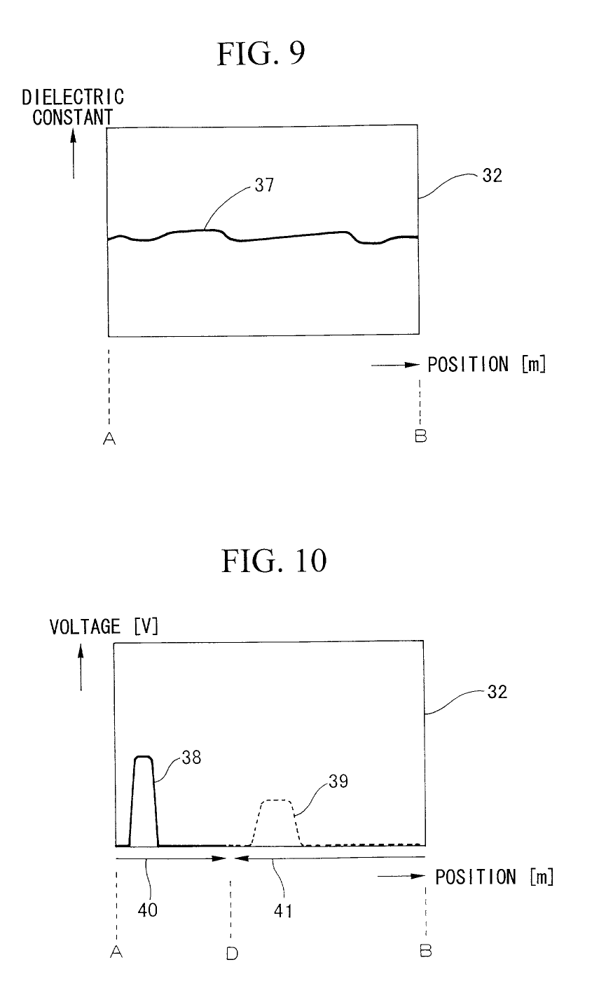

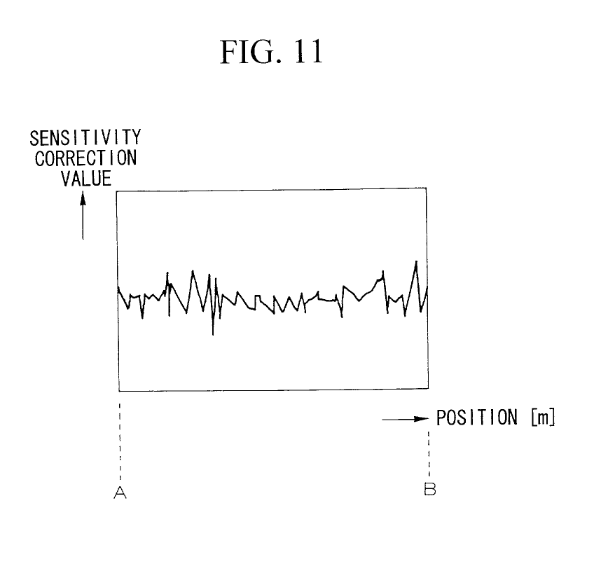

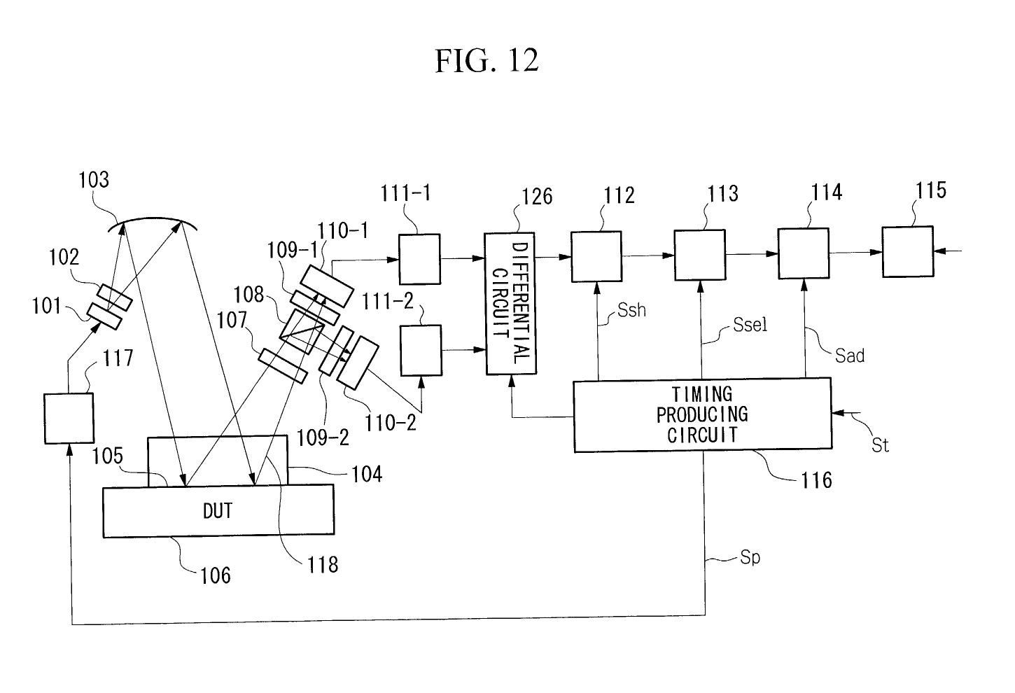

While the dielectric constant is calculated from the travel time of the pulse signal from the straight line A to the straight line B, the section is not limited to the section between the straight lines A and B, and the section between the straight lines A and B may be divided into a plurality of sub-sections. The travel times of the pulse signal in the sub-sections, and the dielectric constants of the respective sub-sections are calculated. Thus, the dielectric constant distribution between the straight lines A and B can be obtained. This dielectric constant distribution can be indicated by the processing/display device 15. An example of the indication is shown in FIG. 9. In the display area 32, the horizontal axis represents the position, the vertical axis represents the dielectric constant, and the dielectric constant distribution 37 is shown.

When the voltage pulse or the pulse of the electric field moves through the DUT 6, the traveling direction of the pulse may be obtained from the variations in the waveforms detected in the DUT 6, and may be indicated by the processing/display device 15. FIG. 10 shows an example of the indication in the display area 32 in which the horizontal axis represents the position, the vertical axis represents the voltage, and the voltage distribution waveforms are displayed. The traveling direction is indicated by the arrow 40 or 41. Alternatively, the color or type of waveforms indicating the voltage distribution may be changed to indicate the traveling direction. In the example, the waveform 38 is indicated by the solid line, while the waveform 39 is indicated by the dashed line.

The traveling direction of the voltage pulse or the pulse with the electric field may be obtained by visual observation, or may be obtained by the following method. The frequency components at the respective positions are produced from the values measured with the lapse of the time. The measured data units which have been temporarily recorded in the recorder 29 are sent to a phase analyzing circuit 30, which then processes the frequency components. The process uses, for example, the Fourier transformation. The real part of the first term in the frequency component should be noted. When the measured waveform is a pulse, it is known that, as the phase of the pulse waveforms moves in the time domain, the real part of the first term in the frequency domain provides a cosine function. Using this theory, when the real part of the first term is known, the phase of the waveform in the time domain can be computed. The traveling direction of the pulse can be obtained from the phase.

The phase analyzing circuit 30 performs the Fourier transformation with the data at the measuring positions on the measuring line to obtain the real parts of the first terms. For example, n measuring points are provided within the range between the straight lines A and B, and the Fourier transformations with n waveforms in the time domain to obtain n real parts Ri of the first terms are performed. A cosine function which fits “A cos θ” is obtained from n data units (real parts). Then, the angles (phase angles) θi are obtained according to θi=cos⁻¹(Ri/A).

The variations in the angles of the points whose traveling directions are to be calculated are detected. For example, when θi−θ(i+1)>0,θ is greater than θ(i+1), and therefore the measured waveform is moving in the direction from i+1 to i. Thus, the traveling direction can be determined. Similarly, the traveling directions at all the points are calculated. Thus, the traveling direction distribution can be obtained. The obtained traveling direction distribution is displayed with and at the same time as the voltage distribution, as shown in FIG. 10. In the example shown in FIG. 10, two waveforms 38 and 39 are traveling toward the point D.

The electrodes (pins) may be provided only in the measurable range (between the straight lines A and B). Thus, the number of electrodes can be reduced.

Preferably, the distribution of intensity of the laser beam received by the line sensors 10-1 and 10-2 with respect to the positions is obtained, and the sensitivities at the respective points are corrected. That is, the measuring sensitivity is proportional to the intensity of the laser beam passing through the electro-optic element 4. When there is a difference between the intensities of the beams 18-1 to 18-n, the measurement sensitivities vary, and the measurement becomes inaccurate. This problem is solved by the correction of the sensitivities depending on the measuring points.

Amplifying circuit 11-1 outputs n output signals. The output signals are sent to a selecting circuit 27-1, and the selecting circuit 27-1 selects one of n output signals. Similarly, the amplifying circuit 11-2 outputs n output signals. The output signals are sent to the selecting circuit 27-2, and the selecting circuit 27-2 selects one of n output signals. The outputs from two selecting circuits 27-1 and 27-2 are summed by an addition circuit 28 to obtain a laser beam intensity signal. The output from the addition circuit 28 is input to a selecting circuit 13. These circuits do not test the DUT 6, and calculate the intensity of the laser beam. Therefore, a sample-hold function is not needed.

The selecting circuit 13 selects the laser beam intensity signal. The A/D converting circuit 14 converts the laser beam intensity signal into a digital signal. The processing/display device 15 calculates the reciprocal number of the value indicated by the digital signal. The reciprocal number is recorded as the position sensitivity correction value by the recorder 29. Similarly, the selecting circuits 27-1 and 27-2 selects all the laser beam intensity signals one at a time, and the position sensitivity correction distribution is calculated and recorded by the recorder 29.

While in the above description the light receiving circuits operates in a differential manner, the received light signals, which contain no signal, may be used as is to correct the position sensitivities when the differential operation is not used.

The present invention can be applied to not only the semiconductor device such as the DUT but also to a printed circuit board,

This invention may be embodied in other forms or carried out in other ways without departing from the spirit thereof. The present embodiments are therefore to be considered in all respects illustrative and not limiting, the scope of the invention being indicated by the appended claims, and all modifications falling within the meaning and range of equivalency are intended to be embraced therein.

1. A method for calibrating a semiconductor testing device, comprising the steps of:
changing a beam emitted from a light source into a linear beam;
sending the linear beam through an electro optic element provided above a target device onto a measuring line on the target device;
detecting a variation in polarization of the beam reflected from the measuring line;
calculating an electric field distribution or a voltage distribution on the measuring line of the target device based on the variation in polarization; and
moving a calibrating device, which produces an electric field from a predetermined point, to specify a measurable point or range.

2. A method according to claim 1, further comprising the step of displaying the measurable point or range.

3. A method according to claim 1, further comprising the step of calculating a relative delay time distribution of the beam on the measuring line of the target device.

4. An apparatus for testing a semiconductor device, comprising:
a beam changer for changing a beam emitted from a light source into a linear beam, and sending the linear beam through an electro optic element provided above a target device onto a measuring line on the target device;
a detector for detecting a variation in polarization of the beam reflected from the measuring line;
a calculator for calculating an electric field distribution or a voltage distribution on the measuring line of the target device based on the variation in polarization; and
a mark indicating a measurable point or range.

5. An apparatus for testing a semiconductor device, comprising:
a beam changer for changing a beam emitted from a light source into a linear beam, and sending the linear beam through an electro optic element provided above a target device onto a measuring line on the target device;
a detector for detecting a variation in polarization of the beam reflected from the measuring line;
a calculator for calculating an electric field distribution or a voltage distribution on the measuring line of the target device based on the variation in polarization; and
a recorder for recording a measurable point or range.

6. A method for calibrating a semiconductor device, comprising the steps of:
changing a beam emitted from a light source into a linear beam;
sending the linear beam through an electro optic element provided above a target device onto a measuring line on the target device;
detecting a variation in polarization of the beam reflected from the measuring line;
calculating an electric field distribution or a voltage distribution on the measuring line of the target device based on the variation in polarization;
correcting the electric field distribution or the voltage distribution based on a relative delay time distribution of the beam on the measuring line of the target device; and
displaying the corrected electric field distribution or the voltage distribution.

7. A method according to claim 6, further comprising the step of recording values obtained by multiplying the relative delay time distribution of the beam on the measuring line by −1.

8. A method for calibrating a semiconductor device, comprising the steps of:
changing a beam emitted from a light source into a linear beam;
sending the linear beam through an electro optic element provided above a target device onto a measuring line on the target device;
detecting a variation in polarization of the beam reflected from the measuring line;
calculating an electric field distribution or a voltage distribution on the measuring line of the target device based on the variation in polarization;
calculating a dielectric constant obtained by dividing a travel time of a pulse between two predetermined points on the measuring line by a distance between the points, and multiplying the divided value by the speed of light; and
displaying the dielectric constant.

9. A method according to claim 8, further comprising the steps of calculating and displaying a dielectric constant distribution for a plurality of points on the measuring line.

10. A method for calibrating a semiconductor device, comprising the steps of:
changing a beam emitted from a light source into a linear beam;
sending the linear beam through an electro optic element provided above a target device onto a measuring line on the target device;
detecting a variation in polarization of the beam reflected from the measuring line;
calculating an electric field distribution or a voltage distribution on the measuring line of the target device based on the variation in polarization;
detecting variations in the electric field distribution or the voltage distribution when a pulse travels on the measuring line; and
specifying a traveling direction of the pulse.

11. A method according to claim 10, further comprising the steps of:
converting the variations in the electric field distribution or the voltage distribution into a frequency;
adapting a real part of a first term of the frequency to a cosine function; and
specifying the traveling direction of the pulse from an angle of the cosine functions for a plurality of points on the measuring line.

12. A method according to claim 11, further comprising the step of displaying the traveling direction of the pulse with the voltage distribution or the electric field distribution.

13. An apparatus for testing a semiconductor device, comprising:
a beam changer for changing a beam emitted from a light source into a linear beam, and sending the linear beam through an electro optic element provided above a target device onto a measuring line on the target device;
a detector for detecting a variation in polarization-of the beam reflected from the measuring line;
a calculator for calculating an electric field distribution or a voltage distribution on the measuring line of the target device based on the variation in polarization; and
an electrode provided in the measurable range.

14. A method for testing a semiconductor device, comprising the steps of:
changing a beam emitted from a light source into a linear beam;
sending the linear beam through an electro optic element provided above a target device onto a measuring line on the target device;
detecting a variation in polarization of the beam reflected from the measuring line;
calculating an electric field distribution or a voltage distribution on the measuring line of the target device based on the variation in polarization;
calculating a reciprocal number of a light intensity at a point on the measuring line; and
multiplying a voltage or an electric field at the point on the measuring line by the reciprocal number to correct the voltage or the electric field.

15. A method according to claim 14, further comprising the step of:
recording the reciprocal number of light intensity at the point on the measuring line.

16. A method according to claim 14, further comprising the steps of:
detecting the variation in polarization of the reflected beam with differential light receiving sections; and
calculating the light intensity based on the sum of outputs from the differential light receiving sections.

17. A method according to claim 14, further comprising the steps of:
detecting the variation in polarization of the reflected beam with a single light receiving section; and
calculating the light intensity based on an output from the single light receiving section indicating the absence of the voltage or the electric field in the target device.
